(19) United States
(12) Patent Application Publication
(10) Pub. No.: US 2013/0015480 A1
(43) Pub. Date: Jan. 17, 2013

(54) SEMICONDUCTOR LIGHT EMMITING DEVICE

(71) Applicants: Yasuharu SUGAWARA, Kanagawa-ken (JP); Yuko Kato, Kanagawa-ken (JP)

(72) Inventors: Yasuharu SUGAWARA, Kanagawa-ken (JP); Yuko Kato, Kanagawa-ken (JP)

(73) Assignee: Kabushiki Kaisha Toshiba, Tokyo (JP)

(21) Appl. No.: 13/404,782

(22) Filed: Feb. 24, 2012

(30) Foreign Application Priority Data
Jul. 14, 2011 (JP) P2011-155454

(51) Int. Cl. H01L 33/60

(52) U.S. Cl. 257/98; 257/E33.072

(57) ABSTRACT

According to one embodiment, in a semiconductor light emitting device, a substrate has a first surface and a second surface to face to each other, and side surfaces each having a first region extending approximately vertically from the first surface toward the second surface side and a second region sloping broadly from the first region toward the second surface side. A semiconductor laminated body is provided on the first surface of the substrate and includes a first semiconductor layer of a first conductivity type, an active layer and a second semiconductor layer of a second conductivity type which are laminated in the order. A reflection film is provided on the second surface of the substrate.

### CROSS REFERENCE TO RELATED APPLICATION

This application is based upon and claims the benefit of priority from the prior Japanese Application No. 2011-155454, filed on Jul. 14, 2011, the entire contents of which are incorporated herein by reference.

### FIELD

Embodiments described herein relate generally to a semiconductor light emitting device.

### BACKGROUND

Heretofore, there are nitride semiconductor light emitting devices configured to reflect light emitted from a light emitting layer to a sapphire substrate side to a nitride semiconductor layer side by a reflection film provided on a rear surface of the sapphire substrate in order to improve light extraction efficiency.

The nitride semiconductor light emitting device is manufactured in the following manner. First of all, a nitride semiconductor layer is formed on a sapphire substrate. Thereafter, the sapphire substrate on which the nitride semiconductor layer is formed is pasted to an adhesive sheet, and the sapphire substrate is diced with a blade and so on to divide into rectangular solid shaped chips.

After the sapphire substrate divided into the chips by expanding the adhesive sheet is transferred to another sheet, a reflection film is formed on a rear surface of the sapphire substrate by a sputtering method and so on.

However, at the time of forming the reflection film, there is a problem that the sputtered reflection film material goes around the side surface of the sapphire substrate, and thereby the reflection film is formed on a portion of the side surface of the sapphire substrate.

As a result, there is a problem that the light extraction efficiency from the side surface of the sapphire substrate is reduced. The reduction of fabrication yield and the rise in fabrication cost are caused, and thereby it becomes difficult to stably manufacture the semiconductor light emitting device.

### BRIEF DESCRIPTION OF THE DRAWINGS

FIGS. 1A and 1B are cross-sectional views showing a semiconductor light emitting device according to a first embodiment;

FIGS. 2A to 2D are cross-sectional views showing steps of manufacturing the semiconductor light emitting device in the sequential order according to the first embodiment;

FIG. 3 is a cross-sectional view showing a semiconductor light emitting device of a comparative example according to the first embodiment;

FIGS. 4A and 4B are cross-sectional views showing steps of manufacturing the semiconductor light emitting device of the comparative example in the sequential order according to the first embodiment;

FIG. 5 is a cross-sectional view showing a semiconductor light emitting device according to a second embodiment;

FIGS. 6A to 6D are cross-sectional views showing steps of manufacturing the semiconductor light emitting device in the sequential order according to the second embodiment;

FIG. 7 is a cross-sectional view showing a semiconductor light emitting device of a comparative example according to the second embodiment;

FIG. 8 is a cross-sectional view showing a semiconductor light emitting device of another comparative example according to the second embodiment;

### DETAILED DESCRIPTION

According to one embodiment, in a semiconductor light emitting device, a substrate has a first surface and a second surface to face to each other, and side surfaces each having a first region extending approximately vertically from the first surface toward the second surface side and a second region sloping broadly from the first region toward the second surface side. A semiconductor laminated body is provided on the first surface of the substrate and includes a first semiconductor layer of a first conductivity type, an active layer and a second semiconductor layer of a second conductivity type which are laminated in the order. A reflection film is provided on the second surface of the substrate.

Hereinafter, embodiments will be described with reference to the drawings. In the drawings, same reference characters denote the same or similar portions.

### First Embodiment

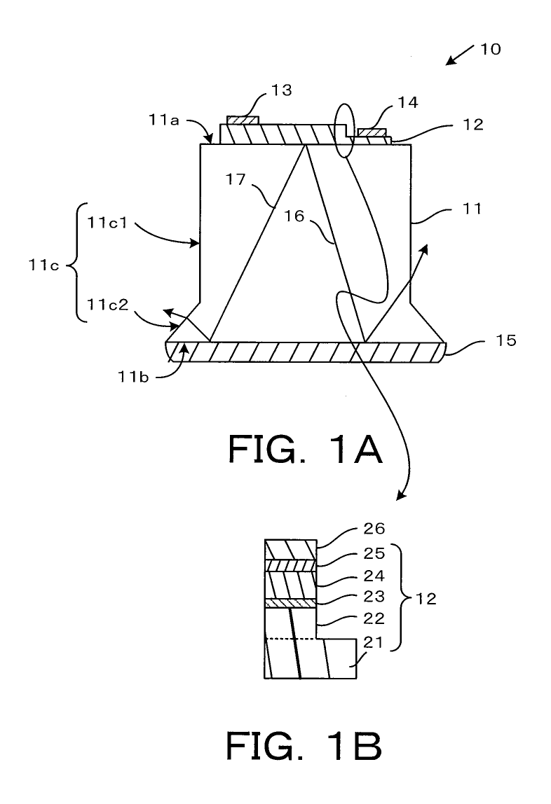

A semiconductor light emitting device of a first embodiment will be described with reference to FIGS. 1A and 1B. The semiconductor light emitting device of the first embodiment is a nitride semiconductor light emitting device. FIGS. 1A and 1B are views each showing the nitride semiconductor light emitting device, FIG. 1A is a side view of the nitride semiconductor light emitting device, and FIG. 1B is a cross-sectional view showing a main portion of FIG. 1A.

As shown in FIGS. 1A and 1B, in a semiconductor light emitting device 10 of the first embodiment, a substrate 11 such as a sapphire substrate whose plane orientation is a C plane has first and second surfaces 11a, 11b which face to each other, and four side surfaces 11c each of which is approximately orthogonal to the first and second surfaces 11a, 11b. The size of the semiconductor light emitting device 10 is 250 μm×250 μm square and the thickness is about 100 to 150 μm, for example.

The side surface 11c has a first region 11c1 which extends approximately vertically from the first surface 11a toward the second surface 11b side and a second region 11c2 which slopes broadly from the first region 11c1 toward the second surface 11b side.

A semiconductor laminated body 12 in which an N-type (a first conductivity type) first nitride semiconductor layer, a nitride active layer, and a P-type (a second conductivity type) second nitride semiconductor layer are laminated in the order is provided on the first surface 11a of the substrate 11.

The first nitride semiconductor layer includes an N-type GaN layer 21 and an N-type GaN clad layer 22, for example, the nitride active layer includes an MQW layer 23, for example, and the second nitride semiconductor layer includes an P-type GaN clad layer 24 and a P-type GaN contact layer 25, for example.

A transparent conductive film 26 is provided on the semiconductor laminated body 12 in order to spread the current and to prevent the electrode material from blocking the light extracted from the P-type GaN contact layer 25 side. A first electrode (a P side electrode) 13, such as an aluminium (Al) film, is provided on a portion of the transparent conductive film 26.

A second electrode (an N side electrode) 14, such as a laminated film of titanium (Ti)/platinum (Pt)/gold (Au) is provided on the N-type GaN layer 21 which is exposed as a result of removing a portion of the semiconductor laminated body 12.

The first electrode 13 and the second electrode 14 are disposed so as to face each other along a diagonal line of the sapphire substrate 11.

A reflection film 15, such as a silver (Ag) film with a thickness of about 200 nm is provided on the second surface 11b of the substrate 11 in order to reflect the light which is emitted from the MQW layer 23 to the substrate 11 side to the semiconductor laminated body 12 side.

Out of the light which is emitted from the MQW layer 23 to the substrate 11 side and is reflected to the semiconductor laminated body 12 side with the reflection film 15, light 16 enters the first region 11c1 of the side surface 11c and is then extracted to the outside and light 17 enters the second region 11c2 of the side surface 11c and is then extracted to the outside.

Though the semiconductor laminated body 12 is well-known, the brief description will be made below. The N-type GaN layer 21 is a base single crystal layer on which the N-type GaN clad layer 22 to the P-type GaN contact layer 25 are grown, and formed in a thickness of about 3 μm, for example. The N-type GaN clad layer 22 is formed in a thickness of about 2 μm, for example.

The MQW layer 23 is formed in such a multiple quantum well structure that a GaN barrier layer with a thickness of 5 nm and an InGaN well layer with a thickness of 2.5 nm are alternately laminated, and the InGaN well layer is located at top layer, for example.

The P-type GaN clad layer 24 is formed in a thickness of about 100 nm, for example, and the P-type GaN contact layer 25 is formed in a thickness of about 10 nm, for example.

A composition ratio x of In in each InGaN well layer (InₓGa₁₋ₓN layer, 0≦x≦1) is set to about 0.1 for the purpose of making the peak wavelength of the light which is extracted from the semiconductor laminated body 12 equal to approximately 450 nm, for example.

The above-described semiconductor light emitting device 10 is configured to prevent the reflection film 15 from adhering to the side surface 11c of the substrate 11 at the time of forming the reflection film 15 by the lower portion of the side surface 11c of the substrate 11 which is protruded as a canopy top. As a result, it is possible to prevent that the extraction efficiency of the light from the side surface 11c is reduced.

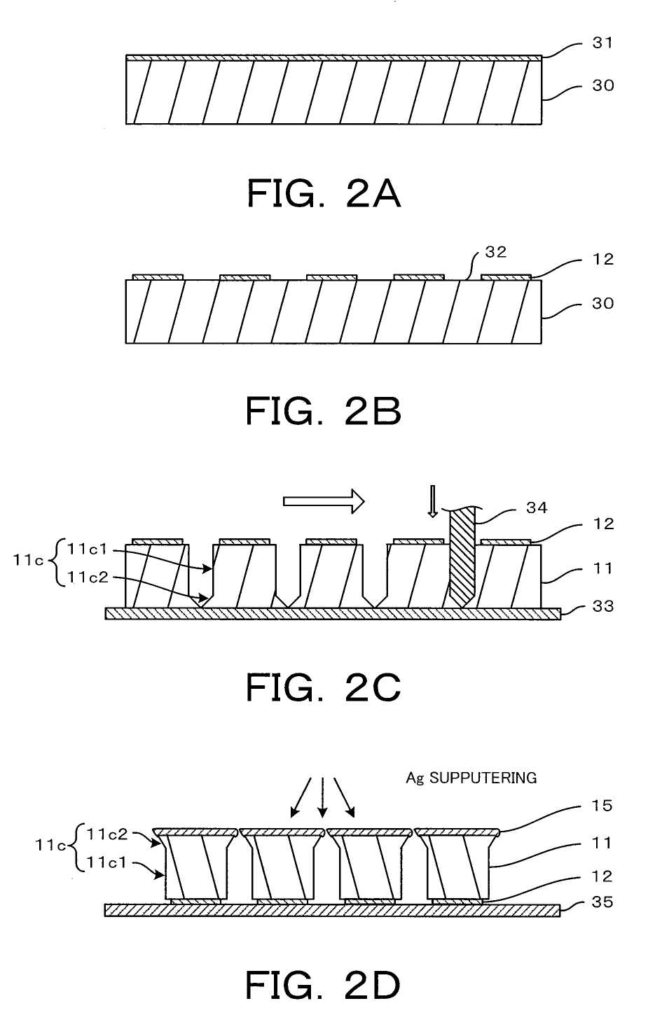

Next, a method of manufacturing the semiconductor light emitting device 10 will be explained with reference to FIGS. 2A to 2D. FIGS. 2A to 2D are cross-sectional views showing steps of manufacturing the semiconductor light emitting device 10 in the sequential order.

As shown in FIG. 2A, First of all, a first semiconductor layer of a first conductivity, an active layer and a second semiconductor layer of a second conductivity are grown on a sapphire substrate 30 in the order by a MOCVD (metal organic chemical vapor deposition) method so as to form the semiconductor laminated body 31.

The method of forming the nitride semiconductor laminated body 31 is well known, but briefly described below. As a preliminary treatment, a sapphire substrate with a diameter of 150 mm and C plane of a plane direction is subjected to organic cleaning and acid cleaning, for example. Thereafter, the resultant sapphire substrate is contained in a reaction chamber of the MOCVD system.

The temperature of the sapphire substrate is raised to 1100° C., for example, by high-frequency heating in a normal-pressure atmosphere of a mixed gas of a nitrogen (N₂) gas and a hydrogen (H₂) gas. Thereby, the surface of the sapphire substrate is etched in gas phase, and a natural oxide film formed on the surface of the sapphire substrate is removed.

The N-type GaN layer 21 with a thickness of 3 μm is formed by using the mixed gas of the N₂ gas and the H₂ gas as a carrier gas while supplying an ammonium (NH₃) gas and a trimethyl gallium (TMG) gas, for example, as process gases, and supplying a silane (SiH₄) gas, for example, as the n-type dopant.

After the N-type GaN clad layer 22 with a thickness of 2 μm is formed likewise, the temperature of the sapphire substrate is decreased to and kept at 800° C. which is lower than 1100° C., for example, while continuing supplying the NH₃ gas with the supply of TMG and the SiH₄ gas stopped.

The GaN barrier layer with a thickness of 5 nm is formed by using the N₂ gas as the carrier gas while supplying the NH₃ gas and the TMG gas, for example, as the process gases. After that, the InGaN well layer with a thickness of 2.5 nm, in which the In composition ratio is 0.1, is formed by supplying a trimethyl indium (TMI) gas as another process gas.

The forming of the GaN barrier layer and the forming of the InGaN well layer are alternately repeated 7 times, for example, while intermittently supplying the TMI gas. Thereby, the MQW layer 23 is obtained.

The undoped GaN cap layer with a thickness of 5 nm is formed while continuing supplying the TMG gas and the NH₃ gas with the supply of TMI stopped.

The temperature of the sapphire substrate is raised to and kept at 1030° C., for example, which is higher than 800° C., in the N₂ gas atmosphere while continuing supplying the NH₃ gas with the supply of the TMG gas stopped.

The p-type GaN clad layer 24 with a thickness of approximately 100 nm, in which the concentration of Mg is 1E20 cm⁻³, is formed by using the mixed gas of the N₂ gas and the H₂ gas as the carrier gas while supplying: the NH₃ gas and the TMG gas as the process gases; and a bis(cyclopentadienyl) magnesium (Cp2Mg) gas as the p-type dopant.

The p-type GaN contact layer 25 with a thickness of approximately 10 nm, in which the concentration of Mg is 1E21 cm⁻³, is formed while supplying an increased amount of Cp2Mg.

The temperature of the sapphire substrate is lowered naturally with the supply of only the carrier gas continued while continuing supplying the NH₃ gas with the supply of the TMG gas stopped. The supplying of the NH₃ gas is continued until the temperature of the sapphire substrate reaches 500° C.

Thereby, the semiconductor laminated body 31 is formed on the sapphire substrate 30 and the P-type GaN contact layer 25 is located in the top surface.

An Indium Tin Oxide (ITO) film is formed as the transparent conductive film 26 on the P-type GaN contact layer 25 using a sputtering method, for example.

As shown in FIG. 2B, patterning of the semiconductor laminated body 31 on which the transparent conductive film 26 has been formed is performed to thereby form dicing lines 32 in a lattice shape. The semiconductor laminated body 31 is sectioned into individual semiconductor laminated bodies 12 which are respectively surrounded by the dicing lines 32.

A portion of the transparent conductive film 26 is removed with a wet etching using a mixed acid of nitric acid and hydrochloric acid to thereby expose a portion of the semiconductor laminated body 12.

An anisotropic etching is performed on a portion of the exposed semiconductor laminated body 12 with an RIE (Reactive Ion Etching) method using chlorine-base gas, for example, to thereby expose the N-type GaN layer 21.

The first electrode 13 (not shown) is formed on a portion of the remaining transparent conductive film 26, and the second electrode 14 (not shown) is formed on the exposed N-type GaN layer 21.

At this stage, multiple nitride semiconductor light emitting devices which are disposed in a lattice shape on the sapphire substrate 30 are obtained.

As shown in FIG. 2C, after the sapphire substrate 30 is pasted on an adhesive dicing sheet 33, the sapphire substrate 30 is cut off along the dicing lines 32 using a so-called V-shaped blade 34 with a tip portion sloping in a forward tapered shape.

At this time, with respect to dicing, the sapphire substrate 30 is not cut deeply into the dicing sheet 33 (not fully cut), but it is proper to stop the cutting at the extent that the tip of the blade 34 touches or does not touch the dicing sheet 33.

Thereby, the diced sapphire substrate 30 becomes the substrate 11. The first region 11c1 of the side surface 11c of the substrate 11 is formed along the line of the side surface of the blade 34. The second region 11c2 of the side surface 11c of the substrate 11 is formed along the line of the sloped side surface at the tip portion of the blade 34. Accordingly, a height of the first region 11c1 of the side surface 11c is larger than a height of the second region 11c2 of the side surface 11e. A width of the first region 11c1 of the side surface 11c is not more than a width of the second region 11c2 of the side surface 11c.

As shown in FIG. 2D, the substrates 11 are pasted in turn on an adhesive sheet 35, and the sheet 35 is expanded to separate the substrates 11 into individual chips. An Ag film with a thickness of about 200 nm is formed as the reflection film 15 on the second surface of the diced sapphire substrate 30 with a sputtering method, for example. Here, the substrate 11 is disposed so that the second surface 11b faces an Ag target (a reflection film source).

At this time, since the second region 11c2 of the side surface 11c acts as a canopy top, it is possible to prevent the sputtered Ag particles from going around and adhering to the side surface 11c.

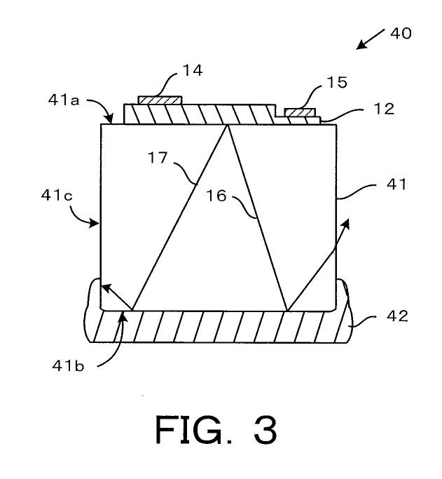

FIG. 3 is a view showing a semiconductor light emitting device of a comparative example. The semiconductor light emitting device of the comparative example means a semiconductor light emitting device which does not have the second region 11c2 of the side surface 11c shown in FIG. 1.

As shown in FIG. 3, in a semiconductor light emitting device 40 of the comparative example, a substrate 41 is formed in a shape of rectangular solid having a first surface 41a and a second surface 41b which face to each other, and side surfaces 41c each of which is approximately vertical to the first and second surfaces 41a, 41b.

The semiconductor laminated body 12 is provided on the first surface 41a of the substrate 41. A reflection film 42 is provided on the second surface 41b of the substrate 41. Since there is nothing corresponding to a canopy top in the substrate 41, the sputtered Ag particles go around the lower portions of the side surfaces 41c and thereby the reflection film 42 adheres to the lower portions of the side surfaces 41c.

Thereby, out of the light which is emitted from the MQW layer 23 to the substrate 41 side and is reflected by the reflection film 42 to the semiconductor laminated body 12 side, though the light 16 enters the side surface 41c and is extracted to the outside, the light 17 enters the side surface 41c to which the reflection film 42 has adhered and cannot be extracted to the outside. As a result, the extraction efficiency of the light from the side surface 41c of the substrate 41 is reduced.

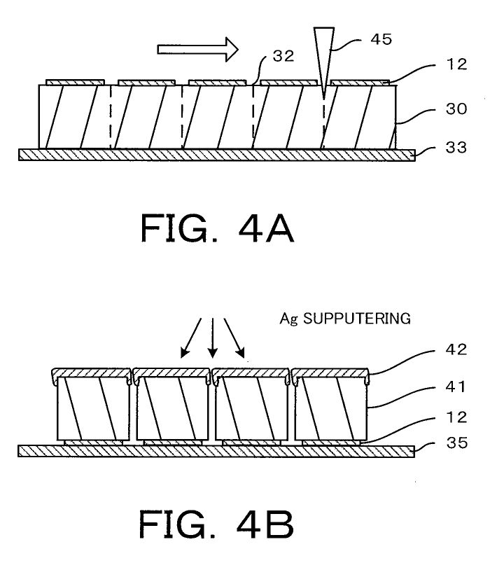

FIGS. 4A and 4B are views showing steps of manufacturing the semiconductor light emitting device of the comparative example. As shown in FIG. 4A, the sapphire substrate 30 pasted on the dicing sheet 33 is diced along the dicing lines 32 with an internal irradiation type laser dicing method, for example. The sapphire substrate 30 is divided into the individual substrates 41 in a shape of rectangular solid.

The internal irradiation type laser dicing method is a method in which a laser beam 45 are concentrated at the inside of the sapphire substrate 30 to form a work-affected layer inside, and the sapphire substrate 30 is separated into chips from the cracks and so on of the work-affected layer used as the starting point by a breaking method.

As shown in FIG. 4B, the substrates 41 are pasted in turn on the sheet 35 to reverse the substrates 41, and then the reflection film 42 is formed on the substrates 41. At this time, since there is nothing corresponding to a canopy top in the substrate 41, it is inevitable that the reflection film 42 adheres to also the lower portions of the side surfaces 41c.

As described above, in the first embodiment, the substrate 11 has the second region 11c2 which slopes broadly from the first region 11cl toward the second surface 11b side

At the time of forming the reflection film 15, since the second region 11c2 acts as a canopy top, it is possible to prevent the reflection film material from going around the side surface 11c. As a result, a semiconductor light emitting device and a manufacturing method of the same which can prevent that the reflection film material adheres to the side surface of the substrate can be obtained.

The description of the first embodiment assumes that the reflection film 15 is made of Ag, but other metal with a high optical reflectivity such as aluminum may be used. In addition, the reflection film 15 may be similarly formed by a vacuum deposition method.

The description of the first embodiment assumes that the substrate is the sapphire substrate, but other transparent substrate, such as an SiC substrate and a GaN substrate can be used. In this case, since SiC and GaN are conductive, the second electrode 14 is formed on the reflection film 15.

### Second Embodiment

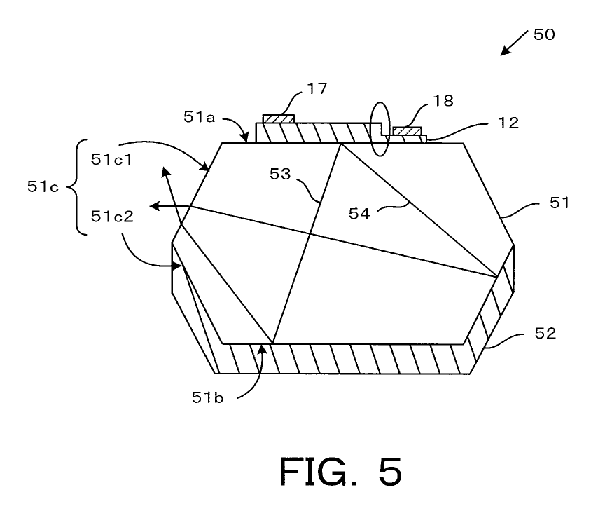

A semiconductor light emitting device of a second embodiment will be described with reference to FIG. 5. FIG. 5 is a cross-sectional view showing the semiconductor light emitting device. In the second embodiment, the same symbols are given to the same constituent portions as in the above-described first embodiment, and the description of these portions will be omitted, and different portions will be described. The point in which the second embodiment is different from the first embodiment is that a reflection film is also formed on the second region of the side surface.

As shown in FIG. 5, in a semiconductor light emitting device 50 of the second embodiment, a substrate 51 has a first surface 51a and a second surface 51b which face to each other and side surfaces 51c.

The side surface 51c has a first region 51c1 which slopes broadly from the first surface 51a toward the second surface 51b side and a second region 51c2 which slopes broadly from the second surface 51b side toward the first surface 51a side.

The semiconductor laminated body 12 is provided on the first surface 51a of the substrate 51. A reflection film 52 is provided on the second surface 51b of the substrate 51 and the second region 51c2 of the side surface 51c.

Out of the light which is emitted from the MQW layer 23 to the substrate 51 side and is reflected to the semiconductor laminated body 12 side with the reflection film 52, light 53 is reflected at the second surface 51b, enters the first region 51c1 of the side surface 51c and is then extracted to the outside. Light 54 is reflected at the second region 51c2 of the side surface 51c, enters the first region 51c1 and is then extracted to the outside.

The above-described semiconductor light emitting device 50 is configured to prevent the reflection film 52 from adhering to the first region 51c1 of the side surface 51c of the substrate 51 and to adhere to the second region 51c2 at the time of forming the reflection film 52 by the central portion of the side surface 51c of the sapphire substrate 51 which is protruded as a canopy top. Accordingly, it is prevented that the extraction efficiency of the light from the side surface 51c is reduced.

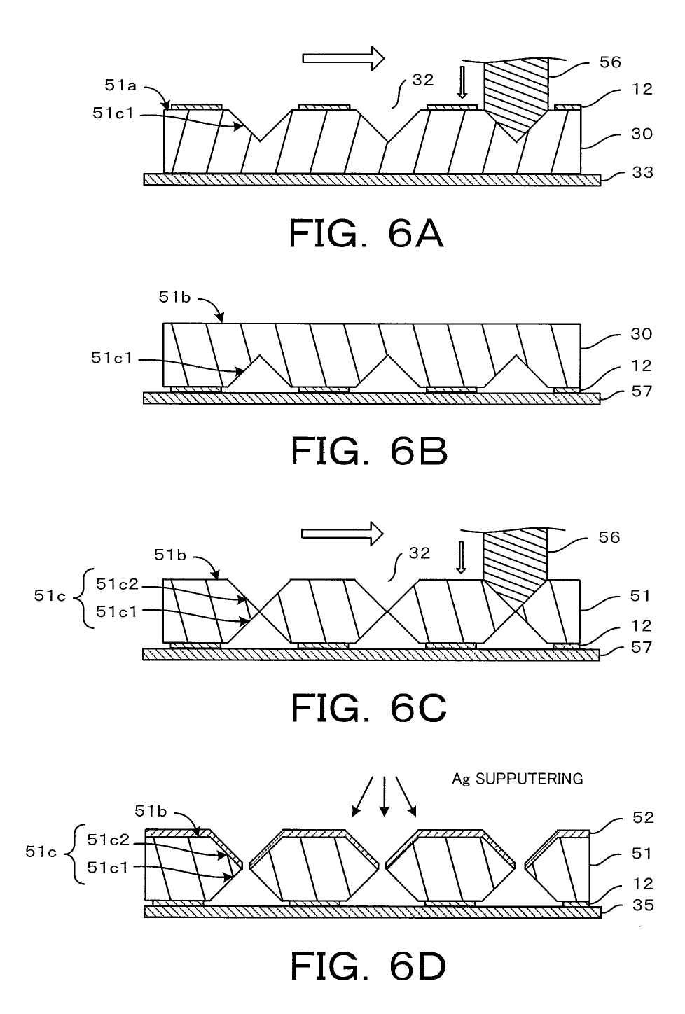

Next, a method of manufacturing the semiconductor light emitting device 50 will be described with reference to FIGS. 6A to 6D. FIGS. 6A to 6D are views showing a main portion of steps of manufacturing the semiconductor light emitting device 50 in the sequential order.

As shown in FIG. 6A, the sapphire substrate 30 pasted on the adhesive dicing sheet 33 is half diced from the first surface 51a side along the dicing line 32 using a blade 56 with a V-shaped tip.

A half dicing amount is not limited in particular, but about a half of the thickness of the sapphire substrate 30 is an appropriate amount.

As shown in FIG. 6B, the sapphire substrate 30 which has been half diced is pasted in turn on a dicing sheet 57 and is then reversed.

As shown in FIG. 6C, the sapphire substrate 30 which has been pasted on the dicing sheet 57 is half diced from the second surface 51b side along the dicing line 32 using the blade 56.

Thereby, the sapphire substrate 30 which has been diced becomes the substrate 51. The first region 51c1 of the side surface 51c of the substrate 51 is formed along the line of the sloping side surface of the blade 56. The second region 51c2 of the side surface 51c of the substrate 51 is formed along the line of the sloping side surface of the blade 56. Accordingly, a height of the first region 51c1 of the side surface 51c is approximately equal to a height of the second region 51c2 of the side surface 51c. An area of the first region 51c1 of the side surface 51c is approximately equal to an area of the second region 51c2 of the side surface 51c.

As shown in FIG. 6D, the substrates 51 are pasted in turn on the adhesive sheet 35, and the sheet 35 is expanded to separate the substrates 51 into individual chips. The reflection film 52 is formed on the second surface 51b of the substrate 51 and the second region 51c2 of the side surface 51c.

At this time, since the second region 51c2 of the side surface 51c acts as a canopy top, it is possible to prevent that the sputtered Ag particles go around and thereby adhere to the first region 51c1 of the side surface 11c.

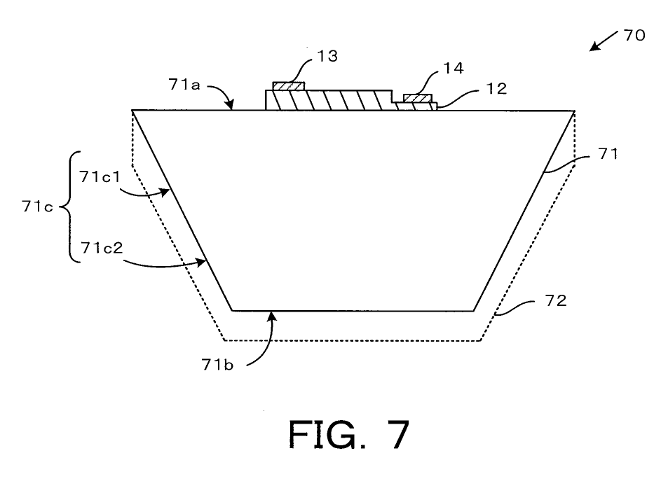

FIG. 7 is a cross-sectional view showing a semiconductor light emitting device of a first comparative example. Here, the semiconductor light emitting device of the first comparative example means a semiconductor light emitting device provided with side surfaces each having a first region and a second region which collectively slopes broadly from a second surface toward a first surface.

As shown in FIG. 7, a semiconductor light emitting device 70 of the first comparative example has a first surface 71a and a second surface 71b which face to each other and side surfaces 71c.

The side surface 71c has a first region 71c1 and a second region 71c2 which collectively slopes broadly from the second surface 71b toward the first surface 71a. The semiconductor laminated body 12 is provided on the first surface 71a of the substrate 71.

In the case of forming the reflection film 72, the reflection film 72 is formed on the second surface 71b of the substrate 71, and is further formed beyond the second region 71c2 of the side surface 71c up to on the first region 71c1 of the side surface 71c. As a result, the extraction efficiency of the light from the side surface 71c is reduced.

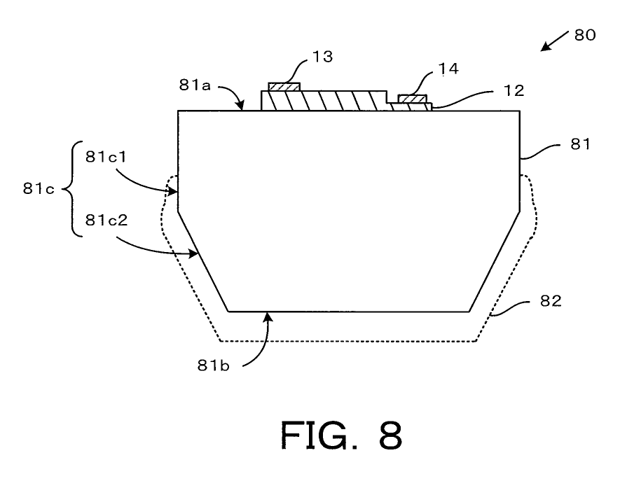

FIG. 8 is a cross-sectional view of a semiconductor light emitting device of a second comparative example. The semiconductor light emitting device of the second comparative example means a semiconductor light emitting device provided with side surfaces each having a first region which extends approximately vertically from the first surface toward the second surface side and a second region which slopes broadly from the second surface toward the first surface side.

As shown in FIG. 8, a semiconductor light emitting device 80 of the second comparative example has a first surface 81a and a second surface which face to each other, and side surfaces 81c.

The side surface 81c has a first region 81c1 which extends approximately vertically from the first surface 81a toward the second surface 81b side and a second region 81c2 which slopes broadly from the second surface 81b toward the first surface 81a side. The semiconductor laminated body 12 is provided on the first surface 81a of the substrate 81.

At the time of forming a reflection film 82, the reflection film 82 is formed not only on the second surface 81b of the substrate 81 and the second region 81c2 of the side surface 81c, but also up to on the first region 81c1 because the reflecting film material has gone around. As a result, the extraction efficiency of the light from the side surface 81c is reduced.

On the other hand, in the semiconductor light emitting device 50 of the second embodiment, since the second region 51c2 of the side surface 51c acts as a canopy top, the reflection film material does not go around the first region 51c1. The reflection film 52 is formed only on the second surface 51b of the substrate 51 and the second region 51c2 of the side surface region 51c. As a result, it is prevented that the extraction efficiency of the light from the side surface 51c is reduced.

As described above, in the second embodiment, the side surface 51c of the substrate 51 has the first region 51c1 which slopes broadly from the first surface 51a toward the second surface 51b side and the second region 51c2 which slopes broadly from the second surface 51b side toward the first surface 51a side so that the central portion of the side surface 51c protrudes.

Thereby, at the time of forming the reflection film 52, there is a merit that it is prevented that the reflection film adheres to the first region 51c1 of the side surface 51c of the substrate 51 and the reflection film can be adhered to the second region 51c2.

Here, the description of the second embodiment assumes that the sapphire substrate 30 is cut off halfway from the first surface 51a side and then the uncut portion of the sapphire substrate 30 is cut off from the second surface 51b side, but it is possible to cut off the sapphire substrate 30 from the second surface 51b side and then cut off from the firsts surface 51a side.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

What is claimed is:

1. A semiconductor light emitting device, comprising:
a substrate with a first surface and a second surface to face to each other, and side surfaces each having a first region extending approximately vertically from the first surface toward the second surface side and a second region sloping broadly from the first region toward the second surface side;
a semiconductor laminated body provided on the first surface of the substrate and including a first semiconductor layer of a first conductivity type, an active layer and a second semiconductor layer of a second conductivity type which are laminated in the order; and
a reflection film provided on the second surface of the substrate.

2. The semiconductor light emitting device of claim 1, wherein the second region slopes in a forward tapered shape.

3. The semiconductor light emitting device of claim 1, wherein a height of the first region of the side surface is larger than a height of the second region of the side surface.

4. The semiconductor light emitting device of claim 1, wherein a width of the first region of the side surface is not more than a width of the second region of the side surface.

5. The semiconductor light emitting device of claim 1, wherein the reflection film is a silver film or an aluminum film.

6. The semiconductor light emitting device of claim 1, wherein the substrate is sapphire and the semiconductor laminated body is a nitride semiconductor laminated body.

7. A semiconductor light emitting device, comprising:
a substrate with a first surface and a second surface to face to each other, and side surfaces each having a first region sloping broadly from the first surface toward the second surface side and a second region sloping broadly from the second surface side toward the first surface side;
a semiconductor laminated body provided on the first surface of the substrate and including a first semiconductor layer of a first conductivity type, an active layer and a second semiconductor layer of a second conductivity type which are laminated in the order; and
a reflection film provided on the second surface of the substrate and the second region of the side surface.

8. The semiconductor light emitting device of claim 7, wherein the first region slopes in a forward tapered shape, and the second region slopes in a reverse tapered shape.

9. The semiconductor light emitting device of claim 7, wherein a height of the first region of the side surface is approximately equal to a height of the second region of the side surface.

10. The semiconductor light emitting device of claim 7, wherein an area of the first region of the side surface is approximately equal to an area of the second region of the side surface.

11. The semiconductor light emitting device of claim 10, wherein the reflection film is a silver film or an aluminum film.

12. The semiconductor light emitting device of claim 7, wherein the substrate is sapphire and the semiconductor laminated body is a nitride semiconductor laminated body.
